(19) United States
(12) Patent Application Publication
(10) Pub. No.: US 2009/0027071 A1
(43) Pub. Date: Jan. 29, 2009

(54) PROBE TAP

(75) Inventor: Eric J. Lanning, San Jose, CA (US)

Correspondence Address: Workman Nydegger;1000 Eagle Gate Tower, 60 East South Temple, Salt Lake City, UT, 84111, US

(73) Assignee: Finsar Corporation, Sunnyvale, CA (US)

(21) Appl. No.: 12/178,045

(22) Filed: Jul. 23, 2008

Related U.S. Application Data
(60) Provisional application No. 60/951,407, filed on Jul. 23, 2007.

(51) Int. Cl. G01R 31/02

(52) U.S. Cl. 324/754

(57) ABSTRACT

A probe tap that monitors data or signals occurring within a device is disclosed. The probe tap can be used to monitor signals, data, or other communications between components of the device. The probe tap can be connected to traces, pins, or other aspects or components of a device and collects data that can be analyzed. The probe tap can include one or more leads that can be removably connected with or between components of a device. The collected data can be provided to an analyzer for analysis. A pod can be included in the probe tap that is used to prepare the data for analysis by the analyzer. Alternately or additionally, the pod can be included in the analyzer.

### CROSS-REFERENCE TO RELATED APPLICATIONS

This application claims the benefit of U.S. Provisional Patent Application Ser. No. 60/951,407, filed Jul. 23, 2007 and entitled PROBE TAP, the contents of which are herein incorporated by reference in their entirety.

### BACKGROUND OF THE INVENTION

1. The Field of the Invention

The present invention relates to monitoring and analyzing signals on a bus. More particularly, embodiments of the invention relate to a probe tap used for monitoring signals between or within a host and a device.

2. The Relevant Technology

The dependence upon the use of data networks to transmit and receive data at high data rates has led to a corresponding interest in the ability to perform real-time monitoring and analysis of that data, or network traffic, so that performance of the network can be evaluated, and problems identified and resolved. Such data monitoring and analysis necessitates the ability to access the network data stream without disrupting the operation of the network. To this end, monitoring systems utilizing network taps are employed. The network taps are configured so that network data can be captured for analysis without interrupting operation of the network.

Substantially less attention has been given to tapping data or signals in other situations or configurations. Network taps are often unable to analyze the traffic that occurs within a host or device itself or that occurs between devices that are more directly connected than network components. Consumer electronics, for example, are examples of systems or configurations where a host communicates with a connected device, but cannot be tapped using conventional network taps.

For example, many consumer devices have ports that are configured to connect with various types of devices such as memory cards. In addition, memory devices are becoming integrated with consumer devices such that they cannot be removed. In this sense, the connections cannot be effectively tapped with conventional systems. The wide variety of configurations as well as the wide variety of protocols complicates the problem of tapping in these instances.

For example, SD (Secure Digital Cards), SDIO (SD Input/Output Cards), MMC (Multimedia Cards) and CE-ATA (Consumer Electronics-Advanced Technology Attachment) are examples of configurations and protocols that are difficult to probe or tap. For example, integrated circuits that communicate using these protocols or other protocols are difficult to probe or tap.

Some of the reasons are related to the physical sizes of devices that use SD, SDIO, MMC or CE-ATA devices. Other reasons are related to the cost. CE-ATA connectors, for example, have a limited number of insertion cycles. Because protocol analyzers are repeatedly connected and disconnected, cost can become a significant issue when analyzing CE-ATA. In addition, many consumer devices do not operate at the same voltage levels. This can complicate the issue of connecting a system to a protocol analyzer when the voltage levels are not known beforehand.

Currently, there is a need for taps that can monitor the data or communications that occur within the host itself or within the device itself or between a host and a device that are more directly connected.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY OF THE INVENTION

These and other limitations are overcome by embodiments of the invention which relate to systems and methods for monitoring signals, data, and/or other communications. More particularly, embodiments of the invention relate to a probe tap for monitoring signals, data, and/or other communications between components of a device or of a host.

Embodiments of the invention allow a protocol analyzer to be used to perform analysis on signals that occur intradevice, such as between integrated circuits (ICs). The analyzer is able to connect with a probe tap that connects with the device. The probe tap may include a module or pod that is typically configured for a particular protocol. The pod then connects with one or more leads that physically tap the signals or lines of a device.

The pod is typically configured or programmed to interact with a particular protocol. For example, the pod typically interfaces with an analyzer and often performs some preprocessing on the tapped signals prior to delivering the tapped signals to the protocol analyzers. The pod can be removed and replaced with another pod when analysis is desired for another protocol. Alternatively, the same pod can be reprogrammed for a different protocol. In either case, the same leads may be used with each pod.

Each lead usually includes a tap board and a finger. The finger is configured to connect to the lines of a device. For instance, the lead may be soldered or otherwise detachably connected with traces, chip pins, bus lines, or other components or aspects of a device. For instance, the fingers can be connected to data lines between a processor and on-board memory. The communication used on-board may be, for example, SD or SDIO. As a result, the tapped signals can be analyzed with a protocol analyzer. Other fingers can be connected to other signals, such as VCC, GND, etc. In addition to pods, embodiments of the invention contemplate the use of logic modules that enable the leads to tap signals such that logic analysis can be performed using a protocol analyzer.

The tap board of the probe tap typically includes the circuitry to allow the signals to be tapped. In one embodiment, the circuitry has a large impedance so as to not interfere with the operation of the device. The tapped signal is then amplified and provided to the analyzer or pod. The tap board may also include the ability to generate a reference voltage such that the logic levels of the tapped signals can be identified even if the voltage level of VCC is unknown.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1A illustrates an environment for implementing embodiments of the invention;

FIG. 1B illustrates an embodiment of the invention including a logic analyzer;

FIG. 2A illustrates a probe tap between two integrated circuits on a host;

FIG. 2B illustrates another embodiment of a probe tap used on an integrated host device;

FIG. 3 illustrates an embodiment of a probe tap between integrated circuits;

FIG. 4 illustrates an embodiment of a lead that can be included in a probe tap;

FIG. 5 illustrates example circuitry on an embodiment of a probe tap; and

FIG. 6 illustrates another embodiment of circuitry that can be included in a probe tap.

### DETAILED DESCRIPTION OF THE PREFERRED EMBODIMENTS

As disclosed in this description and in the accompanying drawings, embodiments of the invention are concerned with probe taps and associated devices, hardware and/or software. Among other things, the probe tap, which may be passive in nature, can be used to monitor data between a host and a device or between two integrated circuits. Embodiments of the invention enable bus lines, traces, chip pins, and the like or any combination thereof to be tapped. For example, a host that operates with a removable memory card can be tapped as described herein. Alternately or additionally, a host with integrated memory or other chips can be tapped as described herein.

SD, MMC, SDIO, CE-ATA are examples of communication protocols that operate with a host and a device or within an integrated host. In another embodiment, these types of communication protocols (e.g., SD, MMC, SDIO, CE-ATA) may occur between integrated circuits or other components on the host or device. In this instance, the circuits or components are often soldered to a printed circuit board and cannot be removed from the device.

By way of example only, the probe tap can be attached to chip pins, trace lines, or other aspects or components of a host or of a device where communication or other signals are present. A probe tap enables a protocol analyzer, for example, to interact with more than network traffic like a conventional tap. Rather, a probe tap as disclosed herein can assist in the evaluation of the signals and circuits that are used to generate network or line traffic or that are used to access a connected device, such as memory, or that occur between components on a single board or device. A probe tap can enable problems to be pinpointed to particular components of a host or other device, monitor communications, logic, signal, protocols, and the like on a host or other device, and the like.

One example of a probe tap is configured for use with a variety of data rates, including, but not limited to, 10/100/1000 Mbit/sec., or even faster rates including Gbit rates. Further, embodiments of the invention can adapt to rates and/or voltages that are specific to the components of a device or to the communication that occurs between chips or other components of a device. Embodiments of the probe tap can be used between chips, for instance, that use SDIO, SD, MMC, or CE-ATA and the like.

In some instances, the data collected by a probe tap can augment the analysis of data collected over a network to analyze issues or protocol. Similarly, data collected using a conventional network tap can augment the analysis of data collected with a probe tap.

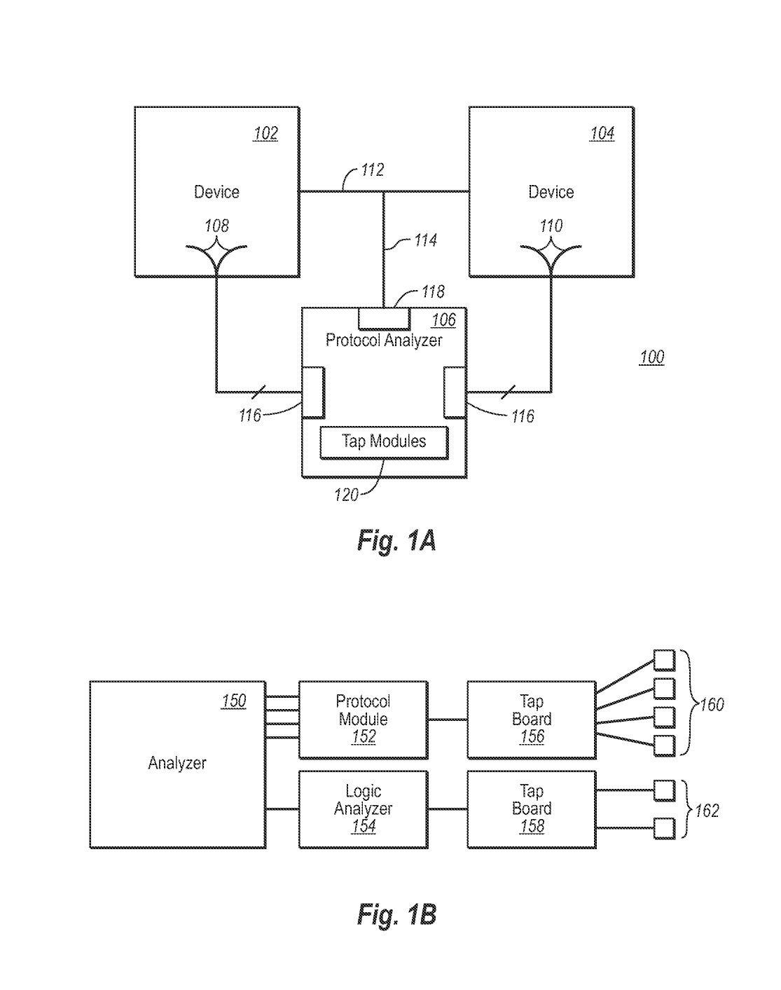

FIG. 1A illustrates an example of an environment for implementing embodiments of the invention. For illustration purposes, the protocol analyzer 106 is shown with three taps 108, 110, and 114. In practice, all of these taps are not required and embodiments of the invention can be implemented with a single tap or with multiple taps.

FIG. 1A illustrates a device 102 that is connected with the device 104 over a connection 112. The connection 112 can be wired or wireless. In this example, the device 102 and 104 can be representative of a client and a server that communicate over a network connection. Alternatively, the devices 102 and 104 may represent a consumer device that communicates with a memory card over a physical connection. In yet another embodiment, the devices may represent integrated circuits of chips on a host or on a single printed circuit board.

A protocol analyzer 106 can be used to tap the connection 112 using the tap 114. The tap 114 can connect to the connection 112 and then capture data or the communication that occurs between the devices 102 and 104.

In this example, a probe tap 108 and 110 are also illustrated. The probe taps 108 and 110 are configured to capture the data or communications that occur within a device. Thus, the tap 108 can collect or capture data, signals, or communications that occur within the device 102. Similarly, the tap 110 can capture data, signals, or communications that occur within the device 104.

For example, when the connection 112 is a network connection, the tap 114 may be a conventional tap that taps the network connection. The taps 108 and 110 may be probe taps that tap lines or traces on the devices 102, 104 themselves. The data collected by the tap 114 can be used to augment the data collected by the taps 108, 110. Also, the protocol analyzer 106 may be able to collect and process data from different taps simultaneously.

In another example, the connection 112 may be traces between two ICs on a device. In this case, the tap 114 is a probe tap that taps the communication between the two ICs. The taps 108, and 110 may be connected to other aspects of the device such as other traces, pins, signals, etc.

In some instances, the protocols that are used for in-device communication may vary or differ from the protocols that are used for network communication. In this example, the protocol analyzer 106 includes pods 116 and 118 that can be used with various taps. For instance, the pod 118 is used with the tap 114 while the pods 116 are used with the taps 108 and 110. The pods 116, for example, may include hardware and/or software that can interpret or partially process the data or signals captured or collected by the corresponding taps. Further, the protocol analyzer may include tap modules 120 that include the software necessary to interpret the collected data. The tap modules can be loaded as needed or based on the pods that are currently connected.

FIG. 1B illustrates another embodiment of the invention and illustrates the scalability and flexibility of a probe tap. In this example, the analyzer 150 is configured to perform protocol analysis. Advantageously, the analyzer 150 may also be configured to perform logic analysis as well. One embodiment of the probe tap includes a protocol module 152. The protocol module 152 is configured to permit the analyzer to receive the tapped signals from a device. Often the protocol module 152 may be a pod, for example, and is typically selected based on the protocol that is expected. Alternatively, the protocol module 152 can include programmable elements (such as an FPGA) that allow it to be programmed on the fly such that multiple protocols can be processed.

The protocol module 152 can connect (permanently or detachably) with a tap board 156 that includes one or more fingers 160. The tap board 156 typically provides the circuitry needed to provide the signals present on the device to the module 152 and then to the analyzer 150. The tap board 156 and the fingers 160 are described in more detail below.

FIG. 1B further illustrates that the analyzer 150 may also be connected with a logic analyzer 154. The logic analyzer 154 may be a separate module that can interface with the analyzer 150 or be configured to preprocess the signals such that the analyzer 150 can more fully perform logic analysis. Typically, the logic analyzer 154 or the protocol analyzer 150 is provided with information related to the specific signals being tapped. For example, one of the fingers 162 may be connected to a particular pin on a processor. The logic analyzer 154 or analyzer 150 would be provided with this information. In this manner, the relationship between signals on the device can be viewed in conjunction with those traces that are communicating using a protocol such as SD or SDIO, etc. The number of fingers on a particular tap board is not limited, and there is no requirement that all of the fingers be used at any given time.

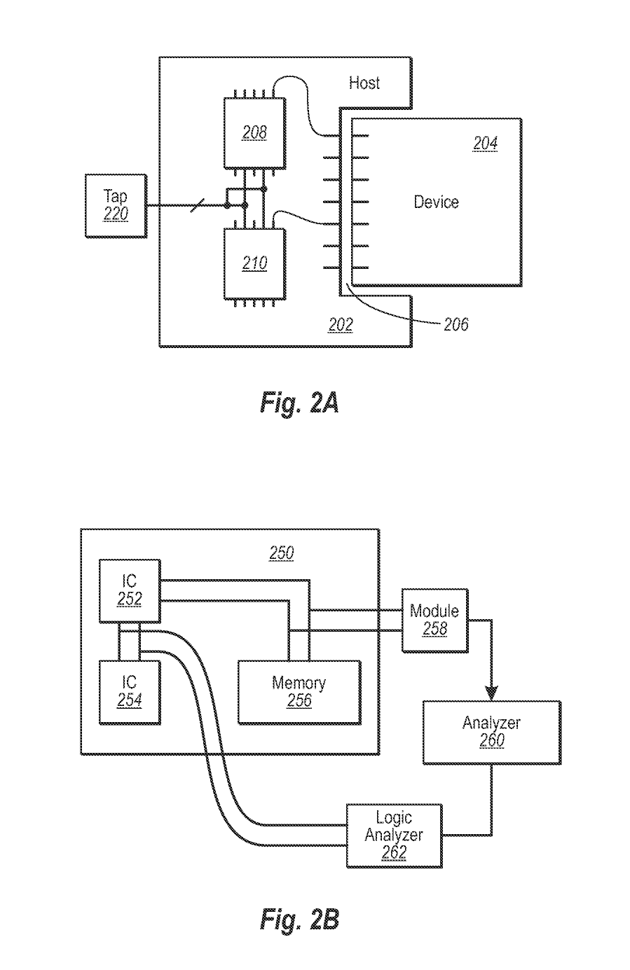

FIG. 2A illustrates another environment where a probe tap can be used and that includes a host 202 and a device 204. The host 202, by way of example only, may be a consumer device (e.g., camera, mp3 player, radio, recorder, laptop computer, desktop computer, cellphone, etc.) and the device 204 may be a memory card. In this example, the connection 206 is appropriate to the device and host, but is often electrical in nature.

The communication between the host 202 and the device 204 typically occurs according to a protocol such as those identified herein. In this example, the host 202 also includes components (e.g., integrated circuits or chips) 208 and 210. The probe tap 220 can be connected to the traces or connections between the components 208 and 210.

The probe tap 220 is illustrated as being attached (detachably or permanently) to the lines between the ICs 208 and 210. In one embodiment, the IC 208 may be a processor and the IC 210 may be memory and may be using a protocol such as SD or SDIO. In this example, the probe tap 220 may include an SD protocol module such that the tapped signals are interpreted by the analyzer accordingly. Similarly, the probe tap 220 could be attached to the signal lines or traces at the interface 206 and tap those lines that operate according to a particular protocol or tap other signals.

FIG. 2B illustrates another embodiment of a consumer device. In this example, the device 250 is integrated in the sense that the components are all placed on the same printed circuit board. Alternatively, an integrated system may indicate that the ICs are connected to the board using pins, ball grid arrays, and the like.

In this example, the analyzer 260 includes a protocol module 258 that is connected to the lines between an IC 252 and memory 256. The communication between the IC 252 and the memory 256 follows a particular protocol (e.g., SD, SDIO, CE-ATA, etc). The signals tapped and provided by the module 258 can be preprocessed by the module 258 or provided directly to the analyzer 260. The logic analyzer 262 may include a probe tap that is connected to signal or lines between the ICs 252 and 254. The IC 252 may be a processor and the IC 254 may be any other type of chip or controller (an audio/video chip, wireless chip, etc.). The signals may be proprietary or otherwise implemented. In any case, the probe tap can be used to tap the signals and the logic analyzer 262 can be used to display the signals or to perform logic analysis. In some instances, the analyzer 260 may be programmed specifically to perform certain functions related to the signals tapped via the logic analyzer 262.

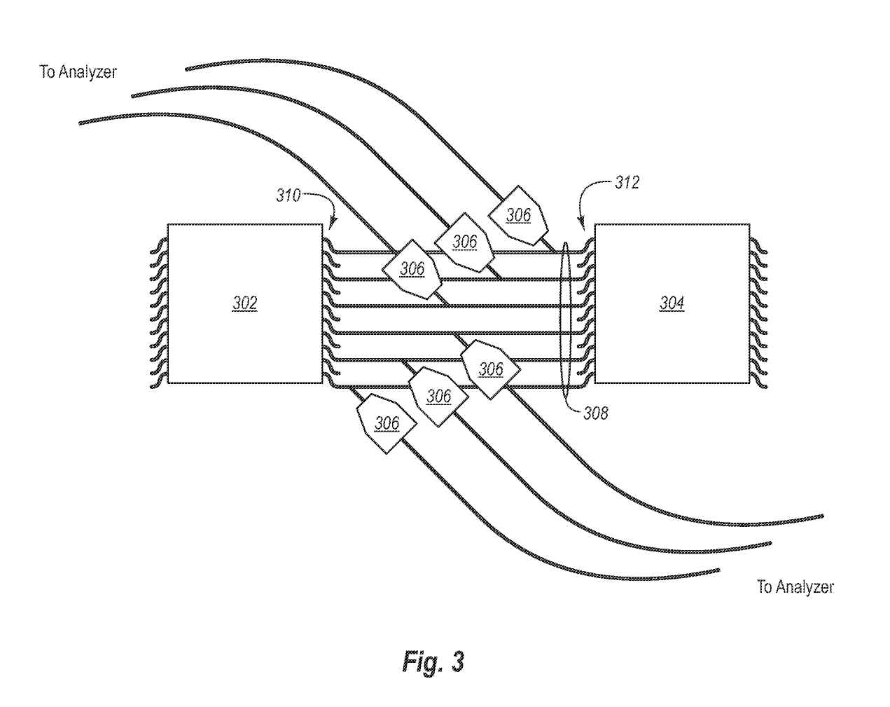

FIG. 3 illustrates another embodiment of a probe tap. In this example, a chip 302 is connected to a chip 304 by one or more traces 308. The chips can be communicating signals, data, or other communications etc. over the traces 308. The chips 302 and 304 may communicate, by way of example only, using SDIO, SD, MMC, or CE-ATA. Other protocols may be used.

Although not shown in FIG. 3, the chips 302 and 304 can be mounted on a printed circuit board (PCB) of a device and can be part of the device as previously discussed. In this example, the probe tap includes multiple leads 306, each lead 306 connected with a particular trace 308. This enables the probe tap to monitor multiple signals within a particular device. In fact, the various leads can be connected to traces between different chips. For instance, the probe tap may have additional leads that are connected between the chip 302 and another chip on the device instead of or in addition to the chip 304.

The number of leads on any embodiment of a probe tap can vary and there is no requirement that all of the leads be used at a given time. This enables some of the leads to remain unconnected for any given use.

FIG. 3 illustrates that the leads 306 are connected with the traces 308. In other embodiments, the leads 306 can be connected to the pins 310 or pins 312, to vias, to output edges, or to any other portion of a device or component of a device.

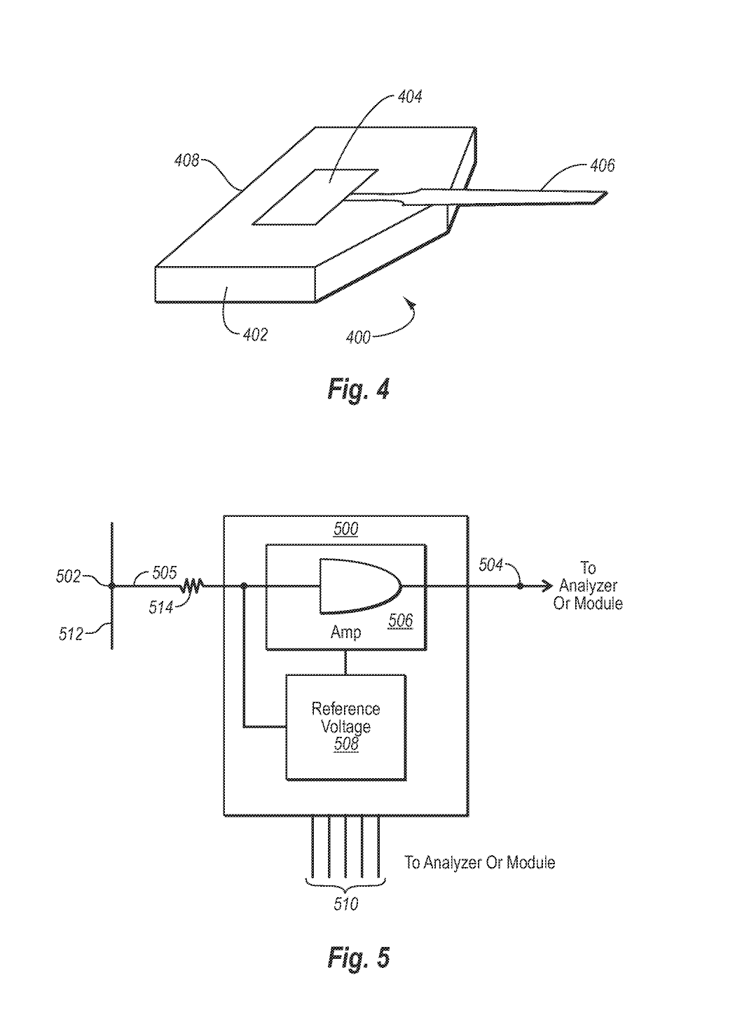

FIG. 4 illustrates an embodiment of a lead 400 that may correspond to one or more of the leads of the probe taps illustrated in FIGS. 1A-3. The lead 400 includes a finger 406 that is typically formed of metal and adapted to connect with a trace, pin or other part of a module. The finger 406 can be soldered to a trace, for example, or connected using conductive tape. The finger 406 can be connected to a PCB 402 that includes circuitry 404. A PCB 402 and circuitry 404 may be included in the tap boards of the probe taps disclosed herein, such as in the tap boards 156, 158 of the probe taps illustrated in FIG. 1B, for instance. The circuitry 404 can provide, by way of example, that the signal can be tapped without interfering with the signal strength. Thus, the circuitry 404 may provide high impedance such that the functionality of the tapped device (not shown in FIG. 4) is not impacted by the connection of the leads. The circuitry 404 can also provide an output 408 that is provided to a pod or to an analyzer for analysis.

When tapping a device as illustrated herein with high impedance, the circuitry 404 may also include an amplifier. This amplifies the tapped signal before providing the tapped signal to the analyzer or other device. Further, the circuitry 404 or other component of the probe tap may include circuitry that enables the probe tap to operate with different signaling voltages. Consumer devices often have different operating voltages from one device to the next. In some instances, certain lines or traces of a device may have a different voltage as well. In this case, the amplification of the signals accounts for the varying voltages.

FIG. 5 illustrates a more detailed embodiment of a lead 500 or of a probe tap. In this example, the line 512 represents one or more lines of a device. For example, the line 512 may correspond to the various lines between a processor and memory that are integrated on the same PCB of a consumer device. In order to tap the line 512, the lead 500 can be connected at the point 502 on the line 512 via a finger 505. The finger 505 may correspond to the finger 406 of FIG. 4. As previously described, connection of the finger 505 to the line 512 may be accomplished using solder, a pressure system, conductive epoxy, and the like.

A high impedance resistor 514 (or resistive network which may also include capacitance and/or inductance where appropriate) insures that the probe tap does not interfere with the signals present on the line 512. Rather, the signal can be tapped and represented as a voltage. The signal can then be amplified in a manner that preferably insures that the voltages at the point 502 and at the point 504 are the same. Thus, the voltage can be amplified by the amplifier 506. The output of the amplifier 506 can be single ended or differential in nature.

The lead 500 (or probe tap in general) can typically be provided with several signals 510, although this is not required in all embodiments. For example, the signals 510 may include by way of example only, VCC, GND, and a voltage reference. These signals may be provided by the analyzer and/or tapped from the device being tapped.

For example, reference voltage circuitry 508 may be provided that includes a circuit that enables the probe tap to distinguish logic highs from logic zeros. In one example, the VCC of the device is tapped and placed through a voltage divider. The output of the voltage divider serves as a reference voltage that the probe tap can use to distinguish between a high and a low signal on the line 512. The reference signal, alternatively, can be provided by the analyzer and be user selected.

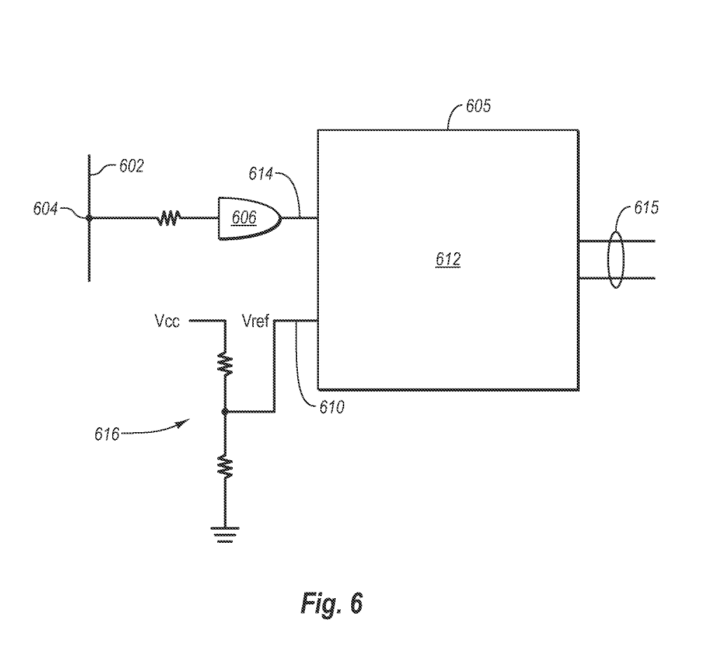

FIG. 6 illustrates one embodiment of the reference voltage 508 of FIG. 5 in more detail. FIG. 6 illustrates a line 602 that is tapped at point 604, which may correspond, respectively, to the line 512 and point 502 of FIG. 5. The tapped signal is then amplified by an amplifier 606, which may correspond to the amplifier 506, and provided to a module 612. As indicated previously, the voltage at point 604 is preferably the same as at the input 614 of the module 612. The input 614 may correspond to the point 504 of FIG. 5 The other input 610 to the module 612 is a reference voltage that is obtained from a voltage divider 616. If the signal at input 614 is higher than the reference voltage at input 610, then the output 615 is a logic high. If the signal at input 614 is lower than the reference voltage at input 610, then the output 615 is a logic low. As previously indicated, the output 615 can be single ended or differential. The module 612 can generate the output 615 based on the comparison between the input 614 and input 610. When multiple lines are tapped, the module 612 may have multiple inputs and multiple outputs.

Generally, embodiments of the invention are suited for operation with any device or host where data is carried over traces or between components or chips of a device. Accordingly, the scope of the invention should not be construed to be limited to any specific device type or host type or data rate.

Further, it should be noted that unlike conventional taps, which use relays with physical switches as described previously, example probe taps according to embodiments of the invention may not include any active components positioned in-line that could cause data packet loss or otherwise interfere with the operation of the device. In other words, regardless of power loss or other fault to the passive tap, there is no loss of communication or data on the device.

Additionally, some embodiments of the probe tap can be employed in a stand-alone configuration where the probe tap obtains data from the device and then passes the data to a remote, or external, device such as an analyzer, bit error rate tester (“BERT”) and/or other device. In yet other implementations however, the probe tap is incorporated into another device, such as a portable analyzer for example. Thus, embodiments of the invention embrace portable analyzers and other devices that incorporate a probe tap.

The embodiments described herein may include the use of a special purpose or general-purpose computer including various computer hardware or software modules, as discussed in greater detail below. A protocol analyzer is an example of a computer as described herein.

Embodiments within the scope of the present invention also include computer-readable media for carrying or having computer-executable instructions or data structures stored thereon. Such computer-readable media can be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium which can be used to carry or store desired program code means in the form of computer-executable instructions or data structures and which can be accessed by a general purpose or special purpose computer. When information is transferred or provided over a network or another communications connection (either hardwired, wireless, or a combination of hardwired or wireless) to a computer, the computer properly views the connection as a computer-readable medium. Thus, any such connection is properly termed a computer-readable medium. Combinations of the above should also be included within the scope of computer-readable media.

Computer-executable instructions comprise, for example, instructions and data which cause a general purpose computer, special purpose computer, or special purpose processing device to perform a certain function or group of functions. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

As used herein, the term “module” or “component” can refer to software objects or routines that execute on the computing system. The different components, modules, engines, and services described herein may be implemented as objects or processes that execute on the computing system (e.g., as separate threads). While the system and methods described herein are preferably implemented in software, implementations in hardware or a combination of software and hardware are also possible and contemplated. In this description, a “computing entity” may be any computing system as previously defined herein, or any module or combination of modulates running on a computing system.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A probe tap comprising:
one or more leads, each lead including:
a printed circuit board;
circuitry mounted to the printed circuit board;
a finger connected with the circuitry, the finger adapted to connect to one or more components of a device, wherein signals present on the one or more components are collected by the finger; and
an output that connects the circuitry to an analyzer and delivers the signals collected by the finger to the analyzer.

2. The probe tap of claim 1, wherein the finger includes metal.

3. The probe tap of claim 1, wherein the one or more components comprise a trace or a pin of a chip.

4. The probe tap of claim 3, wherein the finger has a width similar to a width of the trace of the device.

5. The probe tap of claim 1, wherein the finger is adapted to connect to the one or more components of a device by soldering, conductive tape, a pressure system, or conductive epoxy.

6. The probe tap of claim 1, wherein the circuitry provides an impedance that prevents the lead from interfering with operation of the one or more components of the device.

7. The probe tap of claim 1, wherein the circuitry includes an amplifier adapted to amplify signals present on the one or more components and collected by the finger before providing the signals collected by the finger to the analyzer.

8. The probe tap of claim 1, wherein the circuitry includes reference voltage circuitry adapted to provide a reference voltage the probe tap can use to distinguish between logic highs and logic lows present in the signals collected by the finger.

9. A probe tap comprising:
one or more leads configured to tap one or more signals between components within a device, each lead including:
a finger configured to connect to a line on which signals are present between two components of the device and further configured to collect the signals; and
a tap board including circuitry configured to allow the signals to be collected without interfering with operation of the device; and
one or more protocol modules connected to the one or more leads, each protocol module configured to permit an analyzer to receive the collected signals.

10. The probe tap of claim 9, wherein each of the one or more protocol modules is programmed to interact with one or more particular communication protocols.

11. The probe tap of claim 10, wherein the one or more protocol modules can be replaced by a different protocol module programmed to interact with a different communication protocol to analyze collected signals of the different communication protocol.

12. The probe tap of claim 10, wherein the one or more particular communication protocols include: the Secure Digital (“SD”) protocol, the Secure Digital Input/Output (“SDIO”) protocol, the Consumer Electronics-Advanced Technology Attachment (“CE-ATA”) protocol, the Multimedia Cards (“MMC”) protocol, or any combination thereof.

13. The probe tap of claim 9, wherein at least one of the one or more protocol modules includes programmable elements allowing the at least one protocol module to be programmed on the fly to process multiple communication protocols.

14. The probe tap of claim 9, wherein the tap board circuitry includes a high impedance resistive network that allows the signals to be collected without interfering with operation of the device.

15. The probe tap of claim 9, further comprising reference voltage circuitry included in the tap board circuitry and adapted to provide a reference voltage that the probe tap, the analyzer, or both, can use to distinguish between logic highs and logic lows present in the collected signals.

16. The probe tap of claim 15, wherein the reference voltage is derived from the power supply voltage of the device, the reference voltage circuitry including a voltage divider that receives the power supply voltage as input and produces the reference voltage as output.

17. An analyzer for analyzing tapped data on a bus, the analyzer comprising:
a probe tap configured to capture data communicated between components within a device or a host;
a pod connected to the probe tap and configured to receive the captured data; and
a tap module configured to interpret the captured data.

18. The analyzer of claim 17, further comprising a tap configured to capture data communicated over a network connection between the host and the device.

19. The analyzer of claim 18, wherein the data collected by the tap augments the data collected by the probe tap.

20. The analyzer of claim 17, further comprising one or more leads included in the probe tap, each lead including:
a printed circuit board;
circuitry mounted to the printed circuit board;
a finger connected with the circuitry, the finger adapted to connect to one or more lines between the components, wherein data present on the one or more lines is collected by the finger; and
an output that connects the circuitry to the pod and delivers the data collected by the finger to the pod.
